(19) United States
(12) Patent Application Publication
(10) Pub. No.: US 2022/0390495 A1
(43) Pub. Date: Dec. 8, 2022

(54) NOVEL SPECTRAL ANALYSIS METHOD BASED ON DIGITAL PULSE COMPRESSION AND CHIRP TRANSFORM

(71) Applicant: University of Electronic Science and Technology of China, Chengdu (CN)

(72) Inventors: Ling Tong, Chengdu (CN); Quan Zhao, Chengdu (CN); Xinyi Gao, Chengdu (CN); Xun Gong, Chengdu (CN)

(21) Appl. No.: 17/467,328

(22) Filed: Sep. 6, 2021

(30) Foreign Application Priority Data
Jun. 8, 2021 (CN) 202110630486

(51) Int. Cl. G01R 23/16

(52) U.S. Cl. CPC G01R 23/16

(57) ABSTRACT

The present invention is related to a signal spectrum analysis technology based on linear frequency modulation transformation (LFM) and fast digital pulse compression, which comprises two parts: a circuit for linear frequency modulation signal and an algorithm for fast digital pulse compression. Wherein, in the circuit the modulated chirp signals are obtained by the input signals mixing with the LO chirp signal and then filtered by the band-pass filter the intermediate frequency (IF) chirp signals are produced. The IF signals are composed of the chirp signals with the same frequency band and the chirp rate, but different initial times. Due to the IF chirp signals being orthogonal to each other, the spectrum of the input signals is extracted by the initial time and the orthogonal accumulation. The full spectrum of the input signal is obtained by changing the start position of the sampling data sets along the time axis. The present invention achieves fast high-resolution spectrum analysis by combining the circuit for linear frequency modulation signal and the algorithm for fast digital pulse compression.

### BACKGROUND OF THE INVENTION

The present invention is related to the signal processing technology. More particularly, it is a method of novel spectral analysis based on digital pulse compression algorithm and chirp transform.

As the primary way of spectrum detection, the popular spectrum analyzer is the classical heterodyne frequency sweep spectrometer which can't implement the real-time spectral analysis. Due to the IC technology development, Fourier transform spectrometers based on digital signal processing technology have been proposed. Fourier transform spectrometer based on Fast Fourier Transfer (FFT) can realize the real-time analysis for broadband signals. However, the frequency resolution improvement of FFT spectrometers such as a digital signal processing unit will lead to a significant increase in computation and power consumption.

In recent years, chirp transform spectrometer (CTS) based on radar pulse compression technology has been widely used in space exploration. It is a technology of transforms the detected signals from frequency domain to the time domain. By detecting the time-domain distribution and envelope information of the signal, the spectra of the signal can be obtained by a pulse compression technology using the surface acoustic wave filter (SAW). It is a method of broadband and high-resolution real-time spectrum analysis with small size, light weight, and low power consumption. However, due to some SAW characteristics, such as high attenuation, bandwidth limit, non-ideal dispersion, and other characteristics, the resolution and dynamic range of the spectral analysis system are limited.

The present invention is a method of novel spectral analysis using digital pulse compression.

### SUMMARY

The purpose of the present invention is to provide a spectrum analysis technology based on the combination of linear frequency modulation transformation and fast digital pulse compression.

In the present invention, the input signal and local oscillator (LO) chirp signal are mixed in a mixer, then the output modulated chirp signal from the intermediate frequency (IF) port of the mixer is filtered to the IF chirp signals. Due to the IF band-pass filter, the spectrum distribution of the input signals is transferred to the initial time distribution of the IF chirp signals whose bands are the same. The equal-phase times of the IF chirp signals satisfy a quadratic function. The two sets of orthogonal sampling by time serial tₙ¹ and tₙ² (n:1, 2 . . . N) can be picked up, tₙ¹ and tₙ² corresponding to the orthogonal phases of IF chirp signals. The amplitude of the IF chirp signals is obtained by the respective accumulation of the two sets of the orthogonal samples, and then a quadratic sum. The different initial time of the samples corresponds to the different frequencies of the input signals.

Compared to the classical digital pulse compression, the proposed method in the present invention greatly reduces the computation and power consumption for the sparse spectrum analysis while ensuring sufficient signal spectrum accuracy.

### BRIEF DESCRIPTION OF THE DRAWINGS

For a more complete understanding, further details, and advantages of the present invention, reference is made to the following drawings and descriptions.

FIG. 1 is a functional block diagram of spectrum analysis based on fast digital pulse compression algorithm with linear frequency modulation transformation.

FIG. 2 is a schematic illustration of the modulation, band-pass filtering, and pulse compression for an input signal.

### DETAILED DESCRIPTION OF SPECIFIC EMBODIMENTS

In the following, a specific embodiment of the present invention will be described in detail with reference to the accompanying drawings such that those skilled in the art can better understand the invention. It is noted that well-known functions and configurations are not described in detail to avoid obscuring the present invention.

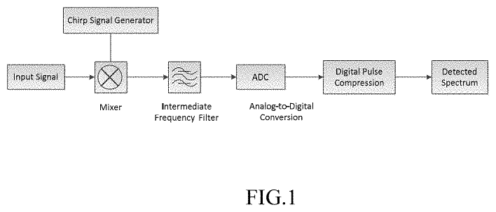

The embodiment shown in FIG. 1 is a functional block diagram of spectrum analysis based on a fast digital pulse compression algorithm with linear frequency modulation transformation. It includes a mixer, band-pass filter, analog-to-digital conversion (ADC), fast digital pulse compression module, and a spectrum detection module.

In the embodiment in FIG. 1, the mixer implements the modulation of input signals with LO chirp signal. The IF chirp signal from the mixer is filtered by a band-pass filter and then transferred by ADC. The fast digital pulse compression algorithm and the spectrum detection module may be implemented using digital circuits.

According to the Fourier theory, any signals can be decomposed into a set of sine signals with different frequencies. Those sine signals are orthogonal to each other. Making use of signal orthogonality, the fast digital pulse compression is as follows.

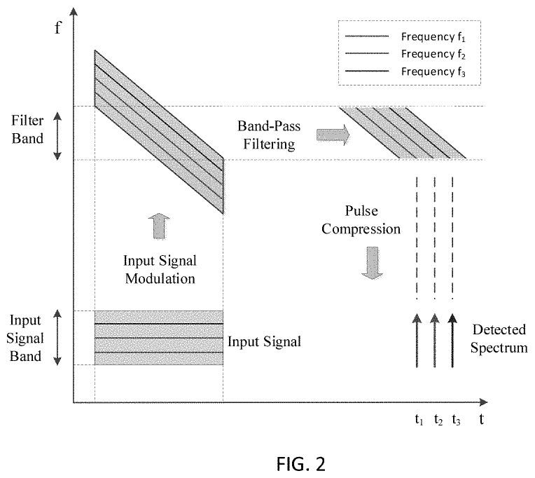

Assume that the input signal contains m spectral components (see Input Signal in FIG. 2 where m=3), and its mathematical representation in the time domain is:

$$s ( t ) = {\sum }_{i = 1}^{m} {a}_{i} cos ( 2 π {f}_{i} t + {φ}_{i} ) \qquad ( 1 )$$

Here aᵢ, fᵢ and φᵢ are the amplitude, frequency and initial phase of the i-th component. The LO chirp signal s_{ec}(t) in FIG. 2 is a linear frequency modulation signal as:

s_{ec}(t)=a_{ec} cos(2π(f_{ec0}t+½kt²)+φ_{ec0})t∈(0,T₀) (2)

The subscript “ec” indicates expanded chirp, and a_{ec}, f_{ec0} and φ_{ec0} are the amplitude, initial frequency and initial phase of the LO chirp signal, k is the chirp rate, T₀ is the modulation period, and the bandwidth of the LO chirp signal is B=kT₀.

The input signal is modulated with the LO chirp signal in the mixer, the modulated chirp signal from the mixer is:

$${s}_{m c} ( t ) = \frac{1}{2} {\sum }_{i = 1}^{m} {a}_{i} \cdot {l}_{m} cos ( 2 π ( ( {f}_{ec 0} + {f}_{i} ) t + \frac{1}{2} k {t}^{2} ) + {φ}_{ec 0} + {φ}_{i} ) + \frac{1}{2} {\sum }_{i = l}^{m} {a}_{i} \cdot {l}_{m} cos ( 2 π ( ( {f}_{i} - {f}_{ec 0} ) t - \frac{1}{2} k {t}^{2} ) - {φ}_{e c 0} + {φ}_{i} ) t ∈ ( 0 , {T}_{0} ) \qquad ( 3 )$$

The subscript “mc” indicates modulated chirp, lₘ is the mixing coefficient set as a unit in the following: In the mixer's linear range, the amplitude of the modulated chirp signal from the IF port of the mixer is linearly associated with the amplitude of the input signal. After the modulated chirp signal is filtered by the IF band-pass filter, the output signal shown in FIG. 2 is:

$${s}_{ifc} ( t ) = \frac{1}{2} {\sum }_{i = 1}^{m} {a}_{i} cos ( 2 π ( ( {f}_{i} - {f}_{e c 0} ) t - \frac{1}{2} k {t}^{2} ) - {φ}_{e c 0} + {φ}_{i} ) \qquad ( 4 )$$

$$t ∈ ( \frac{{f}_{i} - {f}_{bpfstop} - {f}_{e c o}}{k} , \frac{{f}_{i} - {f}_{bpfstart} - {f}_{e c o}}{k} ) \qquad ( 5 )$$

The subscript “ifc” indicates the IF chirp signal filtered by the IF band-pass filter. f_{bpfstart} and f_{bpfstop} are the start and stop frequency of the IF band-pass filter.
In the embodiment shown in FIG. 2, each component of the IF chirp signal has the same band as the band-pass filter and the time duration from formulas (4) and (5). The initial and termination times of the IF chirp signal change with the frequency of the input signals. So the frequency of the input signal is determined by the initial time of the IF chirp signal. Let B_{bpf} is the bandwidth of the filter, tᵢ the initial time of the i-th component of the IF chirp signal is:

$${t}_{i} = \frac{{f}_{i} - {f}_{bpfstop} - {f}_{e c 0}}{k} \qquad ( 6 )$$

Then equation (4) can be further expressed as:

$${s}_{ifc} ( t ) = \frac{1}{2} {\sum }_{i = l}^{m} {a}_{i} cos ( 2 π ( {f}_{bpfstop} ( t - {t}_{i} ) - \frac{1}{2} {k ( t - {t}_{i} )}^{2} ) - {φ}_{e c 0} + {φ}_{i} ) \qquad ( 7 )$$

$$t ∈ ( {t}_{i} , {t}_{i} + \frac{{B}_{bpf}}{k} ) \qquad ( 8 )$$

In the embodiment shown in FIG. 1, the ADC module transfers the IF chirp signal to the digital signal for pulse compression. The first step of pulse compression is selecting two sets of discrete sampling time tₙ¹ and tₙ² (n=1, 2, . . . , N) according to formulae (7) and (8), superscripts 1 and 2 represent that two sets of sampling data are mutually orthogonal. The phases and times corresponding to the two sets of the mutually orthogonal sampling data satisfy the following equations:

$$t - {t}_{i} = {t}_{n}^{1} 2 π ( {f}_{bpfstop} ( {t}_{n}^{1} ) - \frac{1}{2} k ( {t}_{n}^{1} ) ) = {φ}_{r} + 2 n π + Δφ \qquad ( 9 )$$

$$t - {t}_{i} = {t}_{n}^{2} 2 π ( {f}_{bpfstop} ( {t}_{n}^{2} ) - \frac{1}{2} k ( {t}_{n}^{2} ) ) = {φ}_{r} + \frac{π}{2} + 2 n π + Δφ \qquad ( 10 )$$

Here, n=1, 2 . . . N, φᵣ can be an arbitrary constant set to 0, tₙ¹ and tₙ² related to the i-th component of the input signal is from tᵢ to tᵢ+B_{bpf}/k and n is a positive integer from 1 to N. Since the discrete sampling time cannot be accurate at that keeps the two sets of sampling data absolutely orthogonal, a little phase deviation Δφ is introduced in formula (10). N is the sampling number determined by the bandwidth of the pass-band filter, frequency range and chirp rate, as in equation (11):

$$N = {f}_{bpfstop} \frac{{B}_{bpf}}{k} - \frac{1}{2} {k ( \frac{{B}_{bpf}}{k} )}^{2} \qquad ( 11 )$$

From equations (9) and (10), tₙ¹ and tₙ² are:

$${t}_{n}^{1} = \frac{{f}_{bpfstop} - \sqrt{{( {f}_{bpfstop} )}^{2} - 2 n k}}{k} n = 1 , 2 , … N \qquad ( 12 )$$

$${t}_{n}^{2} = \frac{{f}_{bpfstop} - \sqrt{{( {f}_{bpfstop} )}^{2} - 2 ( n + \frac{1}{4} ) k}}{k} n = 1 , 2 , … N \qquad ( 13 )$$

The second step of pulse compression is summing up the two sets of sampling data A₁ₙ and A₂ₙ (n=1, 2 . . . N) extracted following equations (12) and (13) respectively.
For the i-th component, the results are:

$$\begin{matrix}{A}_{1 i} = \frac{1}{2} {\sum }_{n = 1}^{N} {a}_{i} cos ( 2 π ( {f}_{bpfstop} {t}_{n}^{1} - \frac{1}{2} k ( {t}_{n}^{1} ) ) - {φ}_{e c 0} + {φ}_{i} ) \\ = \frac{1}{2} {\sum }_{n = 1}^{N} {a}_{i} cos ( {φ}_{r} + 2 n π + Δφ - {φ}_{e c 0} + {φ}_{i} ) \\ = \frac{1}{2} N {a}_{i} cos ( {φ}_{r} + Δφ - {φ}_{e c 0} + {φ}_{i} )\end{matrix} \qquad ( 14 )$$

$$\begin{matrix}{A}_{2 i} = \frac{1}{2} {\sum }_{n = 1}^{N} {a}_{i} cos ( 2 π ( {f}_{bpfstop} {t}_{n}^{2} - \frac{1}{2} {k ( {t}_{n}^{2} )}^{2} ) - {φ}_{e c 0} + {φ}_{i} ) \\ = \frac{1}{2} {\sum }_{n = 1}^{N} {a}_{i} cos ( {φ}_{r} + \frac{π}{2} + 2 n π + Δφ - {φ}_{e c 0} + {φ}_{i} ) \\ = \frac{1}{2} N {a}_{i} sin ( {φ}_{r} + Δφ - {φ}_{e c 0} + {φ}_{i} )\end{matrix} \qquad ( 15 )$$

For other components (i.e. i≠j) whose initial time is tⱼ, let Δtⱼᵢ=tᵢ−tⱼ, when N is large enough the sums of the sampling data at the sampling time tₙ¹ and tₙ² for the j-th component are respectively:

$${A}_{1 j} = \frac{1}{2} {\sum }_{n = 1}^{N} {a}_{j} cos [ 2 π ( {f}_{bpfstop} ( {t}_{n}^{1} - Δ {t}_{i j} ) - \frac{1}{2} {k ( {t}_{n}^{1} - Δ {t}_{i j} )}^{2} ) - {φ}_{e c 0} + {φ}_{j} ] \to 0 \qquad ( 16 )$$

$${A}_{2 j} = \frac{1}{2} {\sum }_{n - 1}^{N} {a}_{j} cos [ 2 π ( {f}_{bpfstop} ( {t}_{n}^{2} - Δ {t}_{i j} ) - \frac{1}{2} {k ( {t}_{n}^{2} - Δ {t}_{i j} )}^{2} ) - {φ}_{e c 0} + {φ}_{j} ] \to 0$$

(17) According to equation (8) the sum of the orthogonal samples at tₙ¹ and tₙ².

$${A}_{1} = {\sum }_{n = 1}^{N} {A}_{1 n} = {\sum }_{j = 1}^{M} {A}_{1 j} = {A}_{1 i} = \frac{1}{2} N {a}_{i} cos ( {φ}_{r} + Δφ - {φ}_{e c 0} + {φ}_{i} ) \qquad ( 18 )$$

$${A}_{2} = {\sum }_{n = 1}^{N} {A}_{2 n} = {\sum }_{j = 1}^{M} {A}_{2 j} = {A}_{2 i} = \frac{1}{2} {Na}_{i} sin ( {φ}_{r} + Δφ - {φ}_{e c 0} + {φ}_{i} ) \qquad ( 19 )$$

The quadratic sums of A₁ᵢ and A₂ᵢ are related to the power of the i-th component of the input signal according to:

$${a}_{i}^{2} = \frac{2 [ {( {A}_{1} )}^{2} + {( {A}_{2} )}^{2} ]}{{N}^{2}} \qquad ( 20 )$$

The different initial times are related to the different components of the input signal. By changing the start position of the sampling data sets along the time axial the full spectrum of the input signal is obtained.
In the present invention, the frequency resolution can be calculated. If the compression duration is T_{c}, the frequency resolution fᵣ defined by 3 dB bandwidth from equations (14) and (15) is:

$${f}_{r} = \frac{\sqrt{2}}{π {T}_{c}} + \frac{\sqrt{2} {T}_{c}}{π {T}_{c}^{2} + \frac{\sqrt{2}}{k}} \qquad ( 21 )$$

From equation (21) the frequency resolution is related to compression duration T_{c} and chirp rate k.

### GENERAL

Without any loss of generality, the present invention can be used in spectrum analysis or microwave radiometers, and enables effective signal spectrum detection. Additionally, practitioners can also use the present invention more generally in other areas according to their need in spectrum detection and pulse compression.

Unless specifically stated otherwise, as apparent from the following discussions, it is appreciated that throughout the specification discussions utilizing terms such as “detecting”, “measuring”, “signal”, “spectrum analysis” or the like, refer to the action and/or processes. In a similar manner, the term “spectrum detection” may refer to “spectrum identification”, “spectrum analysis”, in the context of any device. Unless specifically stated otherwise, the terms “detection”, “identification” and “analysis” are used interchangeably. The methodologies described herein are, in one embodiment, can be performed by one or more devices or circuits. In such embodiments, any device (respectively circuit) capable of executing this set of signal processing that specifies actions to be taken may be included. Thus, one example is a spectrum analyzer. Another example is a microwave radiometer. Note that when a method includes several elements, e.g., several steps, no ordering of such elements is implied, unless specifically stated. Unless specifically stated otherwise, the terms “equation” and “formula” are used interchangeably.

Note that while some diagram(s) only show(s) a circuit, those skilled in the art understand that several circuits as described above are included, but not explicitly shown or described in order not to obscure the inventive aspect.

Note that, as would be known to one skilled in the art, if the number of units to be produced justifies the cost, any set of instructions may be used in combination with elements. Thus, as will be appreciated by those skilled in the art, embodiments of the present invention may be embodied as a method, an apparatus such as a special purpose apparatus. Accordingly, aspects of the present invention may take the form of a method, an entire hardware embodiment, an entire software embodiment or an embodiment combining software and hardware elements.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may do so. Furthermore, the particular features, structures or characteristics may be combined in any suitable manner, as would be apparent to one of ordinary skill in the art from this disclosure, in one or more embodiments.

Similarly, it should be appreciated that in the above description of example embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description of Embodiments are hereby expressly incorporated into this Detailed Description of Embodiments, with each claim standing on its own as a separate embodiment of this invention.

Furthermore, while some embodiments described herein include some but not other features included in other embodiments, combinations of features of different embodiments are meant to be within the scope of the invention and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures, and techniques have not been shown in detail in order not to obscure an understanding of this description.

As used herein, unless otherwise specified the use of the ordinal adjectives “first”, “second”, “third”, etc., to describe a common object, merely indicate that different instances of like objects are being referred to, and are not intended to imply that the objects so described must be in a given sequence, either temporally, spatially, in ranking, or any other manner.

All publications, patents, and patent applications cited herein are hereby incorporated by reference, except in those jurisdictions where incorporation by reference is not permitted. In such jurisdictions, the Applicant reserves the right to insert portions of any such cited publications, patents, or patent applications if Applicant considers this advantageous in explaining and/or understanding the disclosure, without such insertion considered new matter.

Any discussion of prior art in this specification should in no way be considered an admission that such prior art is widely known, is publicly known, or forms part of the general knowledge in the field.

In the claims below and the description herein, any one of the terms comprising, comprised of, or which comprises is an open term that means including at least the elements/features that follow, but not excluding others. Thus, the term comprising, when used in the claims, should not be interpreted as being limitative to the means or elements or steps listed thereafter. For example, the scope of the expression a device comprising A and B should not be limited to devices consisting only of elements A and B. Any one of the terms including or which includes or that includes as used herein is also an open term that also means including at least the elements/features that follow the term, but not excluding others. Thus, including is synonymous with and means comprising.

Thus, while there has been described what are believed to be the preferred embodiments of the invention, those skilled in the art will recognize that other and further modifications may be made thereto without departing from the spirit of the invention, and it is intended to claim all such changes and modifications as fall within the scope of the invention. For example, any formulas given above are merely representative of procedures that may be used. Functionality may be added or deleted from the block diagrams and operations may be interchanged among functional blocks. Steps may be added or deleted to methods described within the scope of the present invention.

Note that the claims attached to this description form part of the description, so are incorporated by reference into the description, each claim forming a different set of one or more embodiments.

What is claimed is:

1. A method for spectrum analysis based on linear frequency modulation transformation (LFM) and fast digital pulse compression, including:
(1) Modulating the input signals with the LO chirp signal;
(2) Filtering the modulated chirp signal into an IF chirp signal by a band-pass filter;
(3) Converting the IF chirp signal into a digital signal by an ADC;

2. According to the spectrum analysis method described in claim 1, and further including a detection of the input signal frequency using two sets of the sampling data with orthogonal phase and different start points are accumulated respectively, and the square sum of the two results is calculated. The square root of the results is the signal amplitude corresponding to the frequency.

3. According to the spectrum analysis technology mentioned in claim 1, and further incorporating an algorithm of digital pulse compression where the IF signals are composed of the chirp signals with the same frequency band and the chirp rate, but different initial time. The initial time of the chirp signal corresponds to the frequency of the input signal.

4. According to the spectrum analysis technology mentioned in claim 1, and further including a specific method of signal spectrum analysis by changing the start position of the sampling data sets along the time axis the full spectrum of the input signal is obtained by repeating calculations in claim 2 and claim 3. An apparatus for spectrum analysis based on linear frequency modulation transformation (LFM) and fast digital pulse compression, including:
(1) a module for modulating the input signals with the LO chirp signal;
(2) a module for filtering the modulated chirp signal into an IF chirp signal by a band-pass filter;
(3) a module for converting the IF chirp signal into a digital signal by an ADC; and
(4) a module for digital pulse compression.
